(19) United States
(12) Patent Application Publication
(10) Pub. No.: US 2026/0046994 A1
(43) Pub. Date: Feb. 12, 2026

(54) A LIQUID TARGET MATERIAL SUPPLYING APPARATUS, FUEL EMITTER, RADIATION SOURCE, LITHOGRAPHIC APPARATUS, AND LIQUID TARGET MATERIAL SUPPLYING METHOD

(71) Applicant: ASML NETHERLANDS B.V., Veldhoven (NL)

(72) Inventors: William Peter Van Drent, Best (NL); Wyatt Duvall, San Diego, CA (US); Ethan Marcus Swerdlow, San Diego, CA (US); Oliver Zimmerman, San Diego, CA (US)

(21) Appl. No.: 18/707,651

(22) PCT Filed: Sep. 22, 2022
(86) PCT No.: PCT/EP2022/076457

§ 371 Date: May 6, 2024

Related U.S. Application Data
(60) Provisional application No. 63/281,889, filed on Nov. 22, 2021.

(51) Int. Cl. H05G 2/00; G03F 7/00

(52) U.S. Cl. CPC H05G 2/0023; G03F 7/70033; H05G 2/0027

(57) ABSTRACT

The present invention relates to an apparatus for supplying a liquid target material to a radiation source, comprising a reservoir system including a reservoir (410) configured to be connected to an ejection system (450) via an outlet (410a) of the reservoir and a pressurizing system to pressurize solid target material in the reservoir, wherein the apparatus further comprises a heating system (440) arranged between the reservoir and the ejection system to liquify the solid target material after being pressurized in the reservoir, and wherein the pressurizing system is configured to provide a pressure to the solid target material in the reservoir in order to extrude the solid target material through the outlet such that the liquid target material entering the ejection system is at a pressure of at least (200) bar.

### CROSS-REFERENCE TO RELATED APPLICATIONS

This application claims priority of U.S. application 63/281,889 which was filed on Nov. 22, 2021 and which is incorporated herein in its entirety by reference.

### FIELD

The present invention relates to an apparatus for supplying a liquid target material. The present invention further relates to a fuel emitter comprising such a liquid target material supplying apparatus, a radiation source including such a fuel emitter, a lithographic apparatus including such a radiation source, and a method for supplying liquid target material

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern at a patterning device (e.g., a mask) onto a layer of radiation-sensitive material (resist) provided on a substrate.

To project a pattern on a substrate a lithographic apparatus may use electromagnetic radiation. The wavelength of this radiation determines the minimum size of features which can be formed on the substrate. A lithographic apparatus, which uses extreme ultraviolet (EUV) radiation, having a wavelength within the range 4-20 nm, for example 6.7 nm or 13.5 nm, may be used to form smaller features on a substrate than a lithographic apparatus which uses, for example, radiation with a wavelength of 193 nm.

EUV radiation is used in photolithography processes to produce extremely small features in substrates or silicon wafers. Methods to produce EUV radiation include, but are not limited to, converting a material that has an element, for example, xenon, lithium, or tin, with an emission line in the EUV range in a plasma state. In one such method, often termed laser produced plasma (“LPP”), the required plasma can be produced by irradiating a target material, for example, in the form of a droplet, plate, tape, stream, or cluster of material, with an amplified light beam. For this process, the plasma is typically produced in a sealed vessel, for example, a vacuum chamber, and monitored using various types of metrology equipment.

In a current state-of-the-art apparatus for supplying a liquid tin target material in the form of a droplet, a reservoir containing liquid tin is pressurized using Argon gas, which Argon gas is pressurized to a pressure of approximately 200-700 bar. The pressurized liquid tin is then transported to an ejection system configured to provide a stream of droplets of liquid tin to be irradiated by the amplified light beam to form a plasma.

A drawback of liquid tin target material is that it is reactive but needs to be provided to a plasma formation location as pure as possible. Further, the liquid tin target material is at a high pressure and at a high temperature so that the equipment handling the liquid tin target material needs to meet high demands: it has to withstand a high pressure, high temperature and is not allowed to react with the liquid tin target material in any way. Hence, the equipment is made from specific materials that are expensive and require complex fabrication processes.

### SUMMARY

Considering the above, it is an object of the invention to be able to provide an apparatus for supplying target material that handles a reduced amount of liquid target material.

According to an embodiment of the invention, there is provided an apparatus for supplying a liquid target material to a radiation source, comprising a reservoir system including a reservoir configured to be connected to an ejection system via an outlet of the reservoir and a pressurizing system to pressurize solid target material in the reservoir, wherein the apparatus further comprises a heating system arranged between the reservoir and the ejection system to liquify the solid target material after being pressurized in the reservoir, and wherein the pressurizing system is configured to provide a pressure to the solid target material in the reservoir in order to extrude the solid target material through the outlet such that the liquid target material entering the ejection system is at a pressure of at least 200 bar.

According to another embodiment of the invention, there is provided a fuel emitter comprising an apparatus for supplying a liquid target material to a radiation source according to the invention and an ejection system connected to the reservoir of the apparatus.

According to a further embodiment of the invention, there is provided a radiation source comprising a fuel emitter according to the invention.

According to yet another embodiment of the invention, there is provided a lithographic apparatus comprising a radiation source according to the invention.

According to a further embodiment of the invention, there is provided a method for supplying liquid target material to a radiation source, comprising pressurizing solid target material in a reservoir and liquifying the solid target material at a distance from the reservoir, wherein the pressure applied to the solid target material is such that the liquid target material is at a pressure of at least 200 bar.

### BRIEF DESCRIPTION OF THE DRAWINGS

Embodiments of the invention will now be described, by way of example only, with reference to the accompanying schematic drawings, in which:

FIG. 1 depicts a lithographic system comprising a lithographic apparatus and a radiation source;

FIG. 2 schematically depicts a radiation source according to an embodiment of the invention;

FIG. 3 schematically depicts an apparatus for supplying a target material according to an embodiment of the invention in a first situation;

FIG. 4 schematically depicts the apparatus of FIG. 3 in a second situation;

FIG. 5 schematically depicts the apparatus of FIG. 3 in a third situation;

FIG. 6 schematically depicts the apparatus of FIG. 3 in a fourth situation;

FIG. 7 schematically depicts an apparatus for supplying a target material according to another embodiment of the invention;

FIG. 8 schematically depicts an apparatus for supplying a target material according to a further embodiment of the invention in an operational configuration; and

FIG. 9 schematically depicts the apparatus of FIG. 9 in a filling configuration.

### DETAILED DESCRIPTION

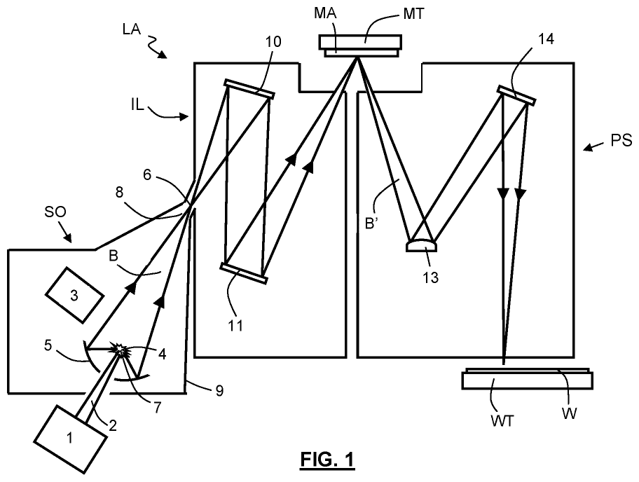

FIG. 1 shows a lithographic system comprising a radiation source SO and a lithographic apparatus LA. The radiation source SO is configured to generate an EUV radiation beam B and to supply the EUV radiation beam B to the lithographic apparatus LA. The lithographic apparatus LA comprises an illumination system IL, a support structure MT configured to support a patterning device MA (e.g., a mask), a projection system PS and a substrate table WT configured to support a substrate W.

The illumination system IL is configured to condition the EUV radiation beam B before the EUV radiation beam B is incident upon the patterning device MA. Thereto, the illumination system IL may include a facetted field mirror device 10 and a facetted pupil mirror device 11. The faceted field mirror device 10 and faceted pupil mirror device 11 together provide the EUV radiation beam B with a desired cross-sectional shape and a desired intensity distribution. The illumination system IL may include other mirrors or devices in addition to, or instead of, the faceted field mirror device 10 and faceted pupil mirror device 11.

After being thus conditioned, the EUV radiation beam B interacts with the patterning device MA. As a result of this interaction, a patterned EUV radiation beam B′ is generated. The projection system PS is configured to project the patterned EUV radiation beam B′ onto the substrate W. For that purpose, the projection system PS may comprise a plurality of mirrors 13,14 which are configured to project the patterned EUV radiation beam B′ onto the substrate W held by the substrate table WT. The projection system PS may apply a reduction factor to the patterned EUV radiation beam B′, thus forming an image with features that are smaller than corresponding features on the patterning device MA. For example, a reduction factor of 4 or 8 may be applied. Although the projection system PS is illustrated as having only two mirrors 13,14 in FIG. 1, the projection system PS may include a different number of mirrors (e.g., six or eight mirrors).

The substrate W may include previously formed patterns. Where this is the case, the lithographic apparatus LA aligns the image, formed by the patterned EUV radiation beam B′, with a pattern previously formed on the substrate W.

A relative vacuum, i.e. a small amount of gas (e.g. hydrogen) at a pressure well below atmospheric pressure, may be provided in the radiation source SO, in the illumination system IL, and/or in the projection system PS.

The radiation source SO shown in FIG. 1 is, for example, of a type which may be referred to as a laser produced plasma (LPP) source. A laser system 1, which may, for example, include a CO₂ laser, is arranged to deposit energy via a laser beam 2 into a fuel, alternatively referred to as target material, such as tin (Sn) which is provided from, e.g., a fuel emitter 3. Although tin is referred to in the following description, any suitable fuel may be used. The fuel may, for example, be in liquid form, and may, for example, be a metal or alloy. The fuel emitter 3 may comprise an ejection system configured to direct tin, e.g. in the form of droplets, along a trajectory towards a plasma formation region 4. The laser beam 2 is incident upon the tin at the plasma formation region 4. The deposition of laser energy into the tin creates a tin plasma 7 at the plasma formation region 4. Radiation, including EUV radiation, is emitted from the plasma 7 during de-excitation and recombination of electrons with ions of the plasma.

The EUV radiation from the plasma is collected and focused by a collector 5. Collector 5 comprises, for example, a near-normal incidence radiation collector 5 (sometimes referred to more generally as a normal-incidence radiation collector). The collector 5 may have a multilayer mirror structure which is arranged to reflect EUV radiation (e.g., EUV radiation having a desired wavelength such as 13.5 nm). The collector 5 may have an ellipsoidal configuration, having two focal points. A first one of the focal points may be at the plasma formation region 4, and a second one of the focal points may be at an intermediate focus 6, as discussed below.

The laser system 1 may be spatially separated from the radiation source SO. Where this is the case, the laser beam 2 may be passed from the laser system 1 to the radiation source SO with the aid of a beam delivery system (not shown) comprising, for example, suitable directing mirrors and/or a beam expander, and/or other optics. The laser system 1, the radiation source SO and the beam delivery system may together be considered to be a radiation system.

Radiation that is reflected by the collector 5 forms the EUV radiation beam B. The EUV radiation beam B is focused at intermediate focus 6 to form an image at the intermediate focus 6 of the plasma present at the plasma formation region 4. The image at the intermediate focus 6 acts as a virtual radiation source for the illumination system IL. The radiation source SO is arranged such that the intermediate focus 6 is located at or near to an opening 8 in an enclosing structure 9 of the radiation source SO.

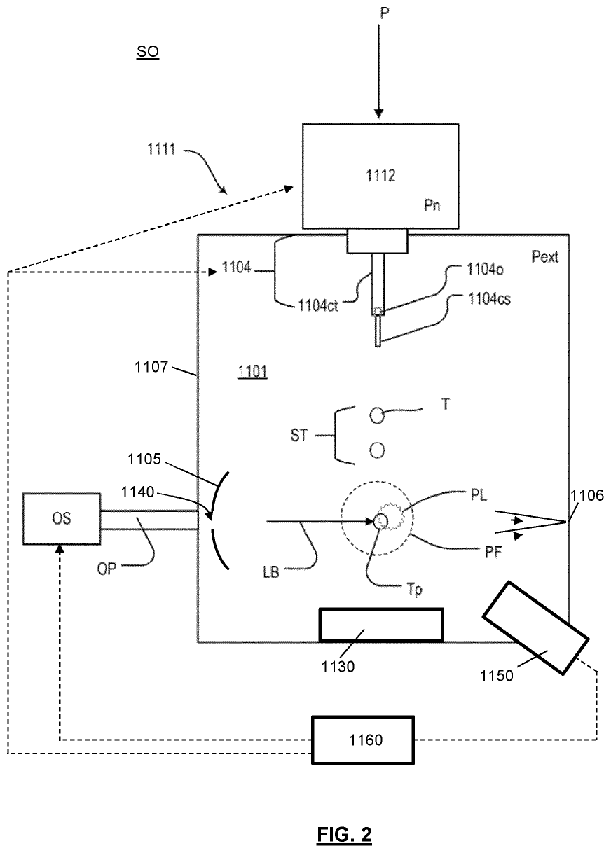

FIG. 2 schematically depicts a radiation source SO according to an embodiment of the invention that may be implemented in the lithographic apparatus LA of FIG. 1. The radiation source SO includes a fuel emitter 1111 similar to the fuel emitter 3 in FIG. 1. The fuel emitter 1111 emits a stream ST of targets T such that a target Tp is delivered to a plasma formation location PF in a low pressure hydrogen environment 1101. The target Tp includes target material. The target material is any material that emits EUV radiation when in a plasma state. For example, the target material can include water, tin, lithium, and/or xenon.

During operation, a vessel 1107 of the radiation source SO is kept under a low pressure hydrogen environment 1101 by means of a hydrogen supply system and a pump system (both not shown). The radiation source SO comprises a light source OS configured to generate a light beam LB, such as a laser beam, and to deliver the light beam LB to the low pressure hydrogen environment 1101 along an optical path OP. The light source OS may include a pulsed laser device, for example, a pulsed, gas-discharge CO₂ laser device producing radiation at about 9300 nm or about 10600 nm, for example, with RF excitation, operating at a relatively high power, for example, 10 kW or higher, and high pulse repetition rate, for example, 40 kHz or more. The pulse repetition rate may be, for example, 50 kHz, 60 kHz, 70 kHz, 80 kHz, 90 kHz, 100 kHz, or more. The plasma formation location PF receives the light beam LB. An interaction between the light beam LB and the target material in the target Tp produces a plasma PL that emits EUV radiation.

The fuel emitter 1111 includes an ejection system 1104, which may include a capillary conduit 1104ct that is fluidly coupled to a reservoir system 1112. The capillary conduit 1104ct defines an orifice 11040. The reservoir system 1112 contains target material under high pressure Pn. A transfer assembly may be provided between the reservoir system 1112 and the ejection system 1104. The target material is in a molten state and is able to flow, and the pressure in the low pressure hydrogen environment 1101 Pext is much lower than the pressure Pn. Thus the target material flows through the orifice 11040. The capillary conduit may be surrounded by a piezo element (not shown) that excites the target material in the conduit such that an acoustic standing wave develops. The target material 102 can exit the orifice 11040 as a jet or continuous stream 1104cs of target material. The jet of target material breaks up into the individual targets T (which can be droplets). The break-up of the jet 1104cs can be controlled such that the individual droplets coalesce into larger droplets that arrive at the plasma formation location PF at a desired rate, e.g. several tens of kHz, for instance 50 kHz or more. The targets T in the stream ST can be approximately spherical, with a diameter in a range of about 15-40 micrometer, for example about 30 micrometer. The stream of targets T may be ejected from the ejection system 1104 by a combination of pressure within the reservoir system 1112 and a vibration applied to the ejection system 1104 by a piezo element (not shown).

In operation, light beam LB, which may be laser energy, is delivered in synchronism with the operation of the fuel emitter 1111, to deliver impulses of radiation to turn each droplet Tp into a plasma PL. In practice, laser energy LB may be delivered in at least two pulses: a pre-pulse with limited energy may be delivered to the droplet before it reaches the plasma formation location PF, in order to transform the target material droplet into a disk-like shape. Then a main pulse of laser energy LB may be delivered to the transformed target material at the plasma formation location PF, to generate the plasma PL. A bucket 1130 may be provided opposite to the ejection system 1104, to capture any target material that is not turned into plasma.

The radiation source SO may include a collector mirror 1105 having an aperture 1140 to allow the light beam LB to pass through and reach the plasma formation location PF. The collector mirror 1105 can be, for example, an ellipsoidal mirror that has a primary focus at the plasma formation location PF and a secondary focus at an intermediate location 1106 (also called an intermediate focus or IF) where the EUV radiation can be output from the radiation source SO and the input to, for example, a lithography tool such as the lithographic apparatus LA of FIG. 1.

The radiation source SO may further include a monitoring system 1150 to measure one or more parameters. The monitoring system 1150 may for instance include one or more target or droplet imagers that provide an output indicative of the position of a droplet, for example, relative to the plasma formation location PF, and provide this output to a master controller 1160. The master controller 1160 may then be configured to compute a droplet position and/or trajectory from which a droplet position error can be computed either on a droplet by droplet basis or on average. The monitoring system 1150 may additionally or alternatively include one or more radiation source detectors that measure one or more EUV radiation parameters, including but not limited to, pulse energy, energy distribution as a function of wavelength, energy within a particular band of wavelengths, energy outside of a particular band of wavelengths, and angular distribution of EUV intensity and/or average power.

The master controller 1160 may be configured to control the light source OS to adjust or set, for example, a light beam position, direction, shaping and/or timing in order to adjust or set the location and/or focal power of the light beam focal spot within the low pressure hydrogen environment 1101. The master controller 1160 may additionally or alternatively be configured to control the ejection system 1104 and/or the reservoir system 1112 of the fuel emitter 1111 to adjust or set, for example, a pressure Pn in the reservoir system 1112 and/or a release point of the targets T as released by the ejection system 1104 to allow the correct amount of target material to be delivered to the plasma formation location PF at the desired moment of time.

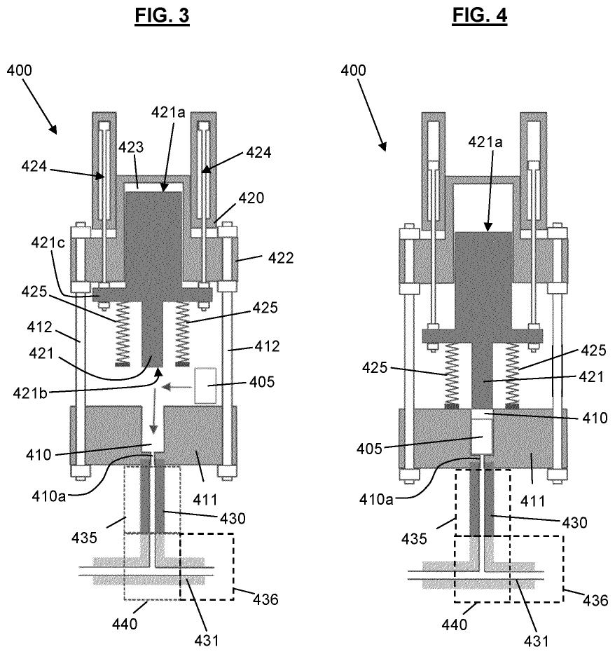

FIGS. 3-6 depict an apparatus 400 for supplying a liquid target material to a radiation source in different working situations. The apparatus 400 may be the apparatus 1112 of the fuel emitter 1111 in FIG. 2.

The apparatus 400 comprises a reservoir system including a reservoir 410 configured to be connected to an ejection system via an outlet 410a of the reservoir 410 as described for instance in relation to FIG. 2. The reservoir system further comprises a pressurizing system 420 to pressurize solid target material in the reservoir 410.

FIG. 3 depicts the apparatus 400 in a first situation in which the reservoir 410 is empty. This first situation may occur during initial start-up when operation of the apparatus 400 is started for a first time and during operation when the reservoir 410 has been emptied.

Depicted in FIG. 3 is a billet 405 of solid target material to be introduced into the reservoir 410 as indicated by the two arrows between the billet 405 and the reservoir 410. The pressurizing system 420 includes a press 421 that is in a retracted position in FIG. 3 allowing the billet 405 to be introduced into the reservoir 410.

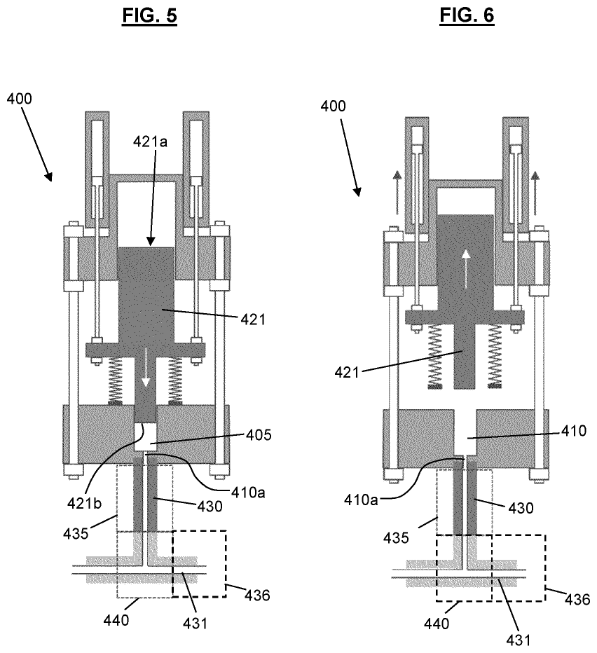

The reservoir 410 is provided in a first block 411 that is connected via rods 412 to a second block 422 holding components of the pressurizing system 420. The second block 422 comprises a pressure chamber 423 configured to receive a rear end of the press 421 with a first pressure surface 421a. The space between the first pressure surface 421a and an opposite wall of the chamber 423 is configured to receive a pressure fluid such as a gas or hydraulic fluid. The pressure fluid applies a force to the first pressure surface 421a urging the press 421 in a direction from the second block 422 to the first block 411, i.e. from a retracted position of the press 421 as shown in FIG. 3 to a pressure position in the reservoir allowing to engage with and apply pressure to the solid target material 405 in the reservoir 410 as shown for instance in FIG. 5.

The second block 422 further houses two cylinders 424 that are connected to a flange 421c of the press 421 and are configured to provide a force to the press 421 urging the press 421 in a direction from the first block 411 to the second block 422, i.e. from a pressure position as shown in FIG. 5 to a retracted position as shown in FIGS. 3 and 6.

As an alternative to the cylinders, the pressurizing system may include an electro-mechanical actuator driving a leadscrew to provide a force to the press urging the press in a direction from the first block 411 to the second block 422 or in an opposite direction.

The solid target material in the billet 405 may not be pure as for instance an oxide layer may have formed on an outer surface due to a reaction with oxygen or because of impurities in the solid target material. The oxide layer may be removed by applying an oxide removing gas, e.g. hydrogen or nitrogen, such as a forming gas, to the solid target material and apply vacuum conditions to the solid target material. It is also possible that only vacuum conditions are applied to prevent the oxide layer from forming and to prevent gas from being trapped in the reservoir 410. Additionally, it is envisaged that the solid target material is liquified first and subsequently subjected to the oxide removing gas and/or the vacuum conditions. This may be advantageous when oxide elements or other impurities need to be removed from the interior of the billet 405. Melting of the target material allows these oxide elements or other impurities to reach the surface and be removed.

The reservoir system is provided with a screen 425 to apply the oxide removing gas and/or the vacuum conditions to the reservoir 410 and the billet of solid target material while the environment at the opposite side of the screen 425 can be maintained at different conditions. In this example, the screen 425 is a flexible screen extending from the flange 421c of the press 421. FIG. 4 depicts the apparatus 400 in a second situation in which the press 421 is lowered by applying pressure to the first pressure surface 421a until the flexible screen 425 engages with the first block 411 around the reservoir 410 holding the billet 405 of solid target material.

Once the flexible screen 425 engages with the first block 411, the vacuum conditions and/or the oxide removing gas may be applied and be given time to do their work before the apparatus 400 is provided in a third situation as shown in FIG. 5 in which the press 421 is provided in contact with the solid target material 405 via a second pressure surface 421b thereby transferring pressure from the pressure fluid at the first pressure surface 421a to the solid target material 405 using the second pressure surface 421b. The third position may alternatively be referred to as pressing position of the press 421.

Although not necessary per se, the first and second pressure surfaces 421a, 421b of the press 421 are not equal with the area of the first pressure surface 421a being larger than the area of the second pressure surface 421b. An advantage thereof is that to achieve a certain desired pressure level to be applied to the solid target material, a lower pressure level of the pressure fluid is needed. For instance, when the first pressure surface 421a is twice the area of the second pressure surface 421b, the pressure in the pressure fluid at the first pressure surface 421a can be half of the pressure to be applied to the solid target material 405.

The reservoir 410 in the first block 411 is connected to a transport system for providing a flow path to an ejection system and possibly to connect the reservoir system to another similar reservoir system that are connected in series or parallel to each other. The transport system in this example comprises a conduit 430 connected to the outlet 410a of the reservoir 410, which conduit 430 in turn is connected to a T-shaped conduit 431 of which one branch is to be connected to an ejection system and the other branch is to be connected to another reservoir system. In this embodiment, the cross-sectional area of the reservoir is larger than the cross-sectional area of the outlet 410a, which cross-sectional area of the outlet 410a is equal to or larger than a cross-sectional area of the conduit 430.

The target material in the billet 405 has a melting temperature. The transport system between the reservoir 410 and the ejection system has a cold zone 435 and a hot zone 436. The conduit 430 is part of the cold zone 435 while the T-shaped conduit 431 is part of the hot zone 436. The cold zone 435 is characterized in that the temperature is below the melting temperature and thus the target material is mainly solid. The hot zone 436 is characterized in that the temperature is above the melting temperature and thus the target material is mainly liquid.

To increase the temperature of the hot zone 436 to above the melting temperature of the target material, the apparatus 400 comprises a heating system 440 arranged between the reservoir 410 and the ejection system. The heating system 440 is configured to liquify the solid target material after being pressurized in the reservoir 410.

The target material in the reservoir 410 and the cold zone 435 of the transport system is solid. When the press 421 applies sufficient pressure to the solid target material in the reservoir 410, the solid target material 410 is forced through the outlet 410a and into the conduit 430 like an extrusion process. In other words, the pressurizing system is configured to extrude the solid target material through the outlet 410a and in this case also through the conduit 430. Upon reaching the conduit 431, the heating system liquifies the solid target material to be supplied to the ejection system for droplet formation as described above in relation to FIG. 2.

The apparatus 400 is able to supply target material to the ejection system as long as solid target material is present in reservoir 410. However, upon reaching a bottom of the reservoir 410, a new billet 405 needs to be introduced into the reservoir 410. To this end, the press 421 is retracted to a retracted position similar to the situation of FIG. 1. Solid target material in the conduit 430 will prevent liquid target material in conduit 431 from flowing back into the reservoir 410. This situation is referred to as a fourth situation. Hence, the apparatus 400 is able to go through a cycle including the first, second, third and fourth situation, after which the apparatus 400 returns to the first situation to repeat the cycle.

In the fourth situation, but also the first and second situation, it is important that the conduit 430 is maintained at a temperature below the melting point of the target material during operation of the apparatus 400. This can for instance be done by providing sufficient distance to the heating system 440 and/or using a heat sink allowing heat to be removed from the transport system before being able to heat the conduit and the solid target material. Alternatively, or additionally, a temperature control system is provided to regulate the temperature of the conduit. Preferably, the temperature of the conduit 430 is held substantially constant. However, variations of the temperature of the conduit 430 may be introduced to control the extrusion of the solid target material through the conduit 430 which has an influence on the pressure in the liquid target material supplied to the ejection system. Hence, in an embodiment, the pressurizing system is configured to provide a pressure to the solid target material in the reservoir such that the liquid target material entering the ejection system is at a pressure of at least 200 bar. This pressure can be measured or determined, e.g. by monitoring the droplets formed by the ejection system, and be adjusted by adjusting the temperature of the conduit 431 which in turn adjusts the flow resistance for the solid target material by the conduit 430.

A benefit of the heating system being arranged between the reservoir 410 and the ejection system is that all components upstream of the heating system are subjected to solid target material. When the target material is a reactive material when liquid, e.g. tin, only the heating system and the components downstream of the heating system need to be able to withstand the reactive liquid target material at a relatively high temperature and pressure.

In an embodiment, the pressurizing system is configured to provide a pressure to the solid target material such that the liquid target material entering the ejection system is at a pressure of at least 700 bar, preferably at least 900 bar, more preferably at least 1100 bar, and most preferably at least 1300 bar. An advantage thereof is that a higher pressure allows to increase the amount of target material per time period that is delivered to the plasma formation location thereby increasing the amount of EUV radiation that can be produced with the radiation source.

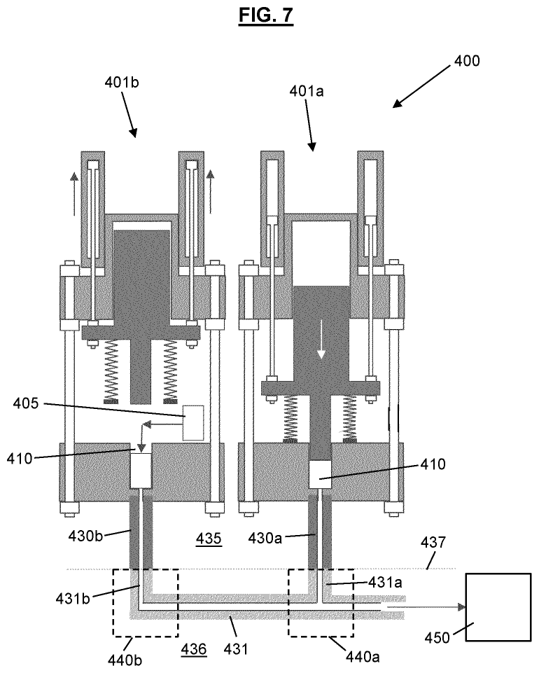

The apparatus 400 of FIGS. 3-6 has a reservoir system that has been described as being connectable to another reservoir system using the T-shaped conduit 431. An example of such an embodiment is depicted in FIG. 7.

FIG. 7 depicts an apparatus 400 for supplying a liquid target material to a radiation source. The apparatus 400 may be the apparatus 1112 of the fuel emitter 1111 in FIG. 2.

The apparatus 400 comprises a first reservoir system 401a, which first reservoir system 401a is in this case identical to the reservoir system described in relation to FIGS. 3-6. The apparatus 400 further comprises a second reservoir system 401b, which second reservoir system is similar to the first reservoir system 401a. The first 401a and the second 401b reservoir system are configured to be connected to an ejection system 450 in parallel. To this end a transport system is provided including a conduit 431 including a branch portion 431a connected to the reservoir 410 of the first reservoir system 401a via a conduit 430a, and including a branch portion 431b connected to the reservoir 410 of the second reservoir system 401b via a conduit 430b.

Indicated is a dashed line 437 that is representative for the boundary between a cold zone 435 and a hot zone 436. The reservoirs 400 and the conduits 430a, 430b are in the cold zone 435 where the temperature is below the melting temperature of the target material. The conduit 431 with the branches 431a, 431b, and preferably also the ejection system 450 is in the hot zone 436 where the temperature is above the melting temperature of the target material.

The apparatus 400 includes a first heating system 440a arranged between the reservoir 410 of the first reservoir system 401a and the ejection system 450 to liquify the solid target material after being pressurized in the reservoir 410 of the first reservoir system 401a. The apparatus 400 further includes a second heating system 440b arranged between the reservoir 410 of the second reservoir system 401b and the ejection system 450 to liquify the solid target material after being pressurized in the reservoir 410 of the second reservoir system 401b. Although not depicted in FIG. 7, the first and second heating systems 440a, 440b may extend along the entire conduit 431. The first and second heating systems 440a, 440b may be integrated into a single heating assembly.

The conduits 430a, 430b are maintained at a temperature below the melting point of the target material during operation of the apparatus 400. This can for instance be done by providing sufficient distance to the first and second heating systems 440a, 440b, respectively, and/or using a heat sink allowing heat to be removed from the transport system before being able to heat the conduits 430a, 430b and the solid target material contained in there. Alternatively, or additionally, a temperature control system is provided to regulate the temperature of the conduits 430a, 430b. Hence, the conduits 430a, 430b function as regulation devices configured to control a flow of target material from the respective reservoir 410.

An advantage of the apparatus 400 of FIG. 7 is that target material can be continuously supplied to the ejection system even when one reservoir system 401a or 401b is temporarily unavailable. As described in relation to FIGS. 3-6. A reservoir system goes through a cycle in which only the third situation allows to supply liquid target material to the ejection system 450. After emptying the reservoir, a new billet 405 of target material needs to be introduced into the reservoir by going through the fourth, first and second situations. In these situations, the reservoir system is not able to supply liquid target material to the ejection system 450. However, by providing two reservoir systems it is possible to allow one reservoir system to go through a refill cycle, i.e. including the fourth, first and second situations, while the other reservoir system is in the third situation in which it is able to supply liquid target material to the ejection system. The roles can be reversed when the reservoir gets empty. It is envisaged that for a predetermined period of time, both reservoir systems are both in the third situation allowing a smooth handover of one reservoir system to the other reservoir system.

In FIG. 7, the first reservoir system 401a is in the third situation corresponding to FIG. 5 while the second reservoir system 401b is in the first situation corresponding to FIG. 3.

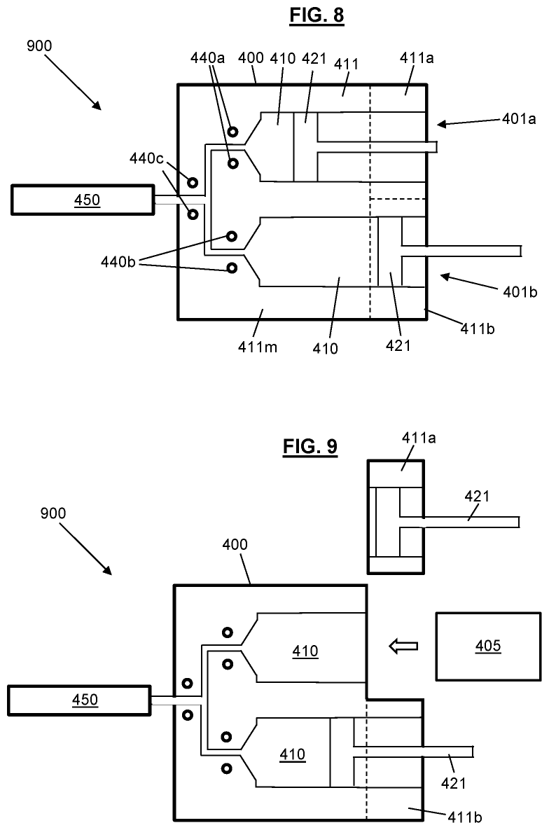

FIGS. 8 and 9 depict a schematic cross-sectional view of a fuel emitter 900 according to an embodiment of the invention including an ejection system 450 for supplying a stream of droplets of target material to a plasma formation location as described above in more detail, and an apparatus 400 connected to the ejection system 450 for supplying liquid target material to the ejection system 450.

The apparatus 400 is here embodied as a block 411 for housing a first reservoir system 401a and a second reservoir system 401b. Each of the first and second reservoir systems 401a, 401b comprises a reservoir 410 and press 421 moveably arranged inside the respective reservoir 410 to apply pressure to solid target material in the reservoir 410.

The apparatus 400 further comprises a first heating system 440a to liquify solid target material after being pressurized in the reservoir 410 of the first reservoir system 401a, and a second heating system 440b to liquify solid target material after being pressurized in the reservoir 410 of the second reservoir system 401b. In this embodiment, also a third heating system 440c is provided to keep the target material in liquid form when the target material is supplied to the ejection system 450.

The block 411 comprises a main portion 411m for housing the main portions of the reservoirs 410, the first, second and third heating systems, and the transport system connecting the reservoirs 410 to the ejection system. The block 411 further comprises a first portion 411a associated with the first reservoir system 401a and a second portion 411b associated with the second reservoir system 401b. The first and second portions 411a, 411b can be moved relative to the main portion 411m as shown for the first portion 411a in FIG. 9 to allow the introduction of a billet 405 of target material. The press 421 of the first reservoir system 401a can be positioned in a retracted position in the first portion 411a to move along with the first portion 411a to make way for the billet 405. The same applies to the press 421 of the second reservoir system.

In FIG. 8, liquid target material is supplied from the reservoir 410 of the first reservoir system to the ejection system 450. To this end, solid target material is pushed out of the reservoir 410 into the transport system by the press 421 and subsequently liquified by the first heating system 440a. The second heating system 440b is preferably not activated to keep the target material in the corresponding transport system part solid to prevent any flow of target material from or to the second reservoir system. While the first reservoir system is supplying target material to the ejection system, the reservoir 410 of the second reservoir system may be filled with a billet of target material. When the reservoir 410 of the first reservoir is nearly depleted, the second reservoir system may be operated by applying the same pressure to the solid target material in the reservoir 410 of the second reservoir system as is applied in the reservoir 410 of the first reservoir system, and by activating the second heating system 440b allowing the second reservoir system to take over the supplying of target material to the ejection system. Once, the second reservoir system and second heating system are fully operational, the first heating system 440a may be deactivated and subsequently the pressure may be released. The press 421 of the first reservoir system can then be retracted into the first portion 411a.

FIG. 9 shows the press 421 of the first reservoir system retracted into the first portion 411a and the first portion 411a moved sideways to allow a billet 405 to be introduced into the reservoir 410 of the first reservoir system.

Although specific reference may be made in this text to the use of lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools. Such a lithographic tool may use vacuum conditions or ambient (non-vacuum) conditions.

Although specific reference may have been made above to the use of embodiments of the invention in the context of optical lithography, it will be appreciated that the invention, where the context allows, is not limited to optical lithography and may be used in other applications, for example imprint lithography.

Where the context allows, embodiments of the invention may be implemented in hardware, firmware, software, or any combination thereof. Embodiments of the invention may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic storage media; optical storage media; flash memory devices; electrical, optical, acoustical or other forms of propagated signals (e.g. carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc. and in doing that may cause actuators or other devices to interact with the physical world.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the clauses and claims set out below.

### CLAUSES

1. An apparatus for supplying a liquid target material to a radiation source, comprising a reservoir system including a reservoir configured to be connected to an ejection system via an outlet of the reservoir and a pressurizing system to pressurize solid target material in the reservoir, wherein the apparatus further comprises a heating system arranged between the reservoir and the ejection system to liquify the solid target material after being pressurized in the reservoir, and wherein the pressurizing system is configured to provide a pressure to the solid target material in the reservoir in order to extrude the solid target material through the outlet such that the liquid target material entering the ejection system is at a pressure of at least 200 bar.
2. An apparatus according to clause 1, wherein the pressurizing system is configured to provide a pressure to the solid target material such that the liquid target material entering the ejection system is at a pressure of at least 700 bar, preferably at least 900 bar, more preferably at least 1100 bar, and most preferably at least 1300 bar.
3. An apparatus according to clause 1 or 2, wherein the reservoir is configured to receive a billet of solid target material, and wherein the pressurizing system comprises a press that is moveable between a pressing position in the reservoir allowing to engage with and apply pressure to the solid target material in the reservoir, and a retracted position in which a billet of solid target material can be introduced into the reservoir.
4. An apparatus according to clause 3, wherein the pressurizing system comprises a hydraulic system using a hydraulic fluid to apply pressure to the press to move the press from the retracted position to the pressure position.
5. An apparatus according to any of clauses 1-4, wherein a conduit is arranged between the reservoir of the reservoir system and the heating system, which conduit is configured to be maintained at a temperature below a melting point of the target material during operation of the apparatus.
6. An apparatus according to clause 5, further comprising a temperature control system to regulate the temperature of the conduit.
7. An apparatus according to any of clauses 1-6, further comprising a vacuum system to apply vacuum conditions to the reservoir.
8. An apparatus according to any of clauses 1-7, further comprising a gas supply system to provide an oxide removing gas to the reservoir.
9. An apparatus according to any of clauses 1-8, further comprising a regulation device configured to control a flow of target material from the reservoir.
10. An apparatus according to any of clauses 1-9, wherein the reservoir system is a first reservoir system, and wherein the apparatus further comprises a similar second reservoir system configured to be connected to the ejection system in parallel with the first reservoir system.
11. An apparatus according to clause 10, wherein the heating system is configured to liquify the solid target material after being pressurized in the reservoir of the second reservoir system.
12. An apparatus according to clause 10, wherein the heating system is a first heating system, and wherein the apparatus further comprises a second heating system configured to liquify the solid target material after being pressurized in the reservoir of the second reservoir system.
13. An apparatus according to any of clauses 10-12, further comprising a regulation device configured to control a flow of target material from the reservoir of the second reservoir system.
14. An apparatus according to any of clauses 1-13, wherein the target material is tin.
15. A fuel emitter comprising an apparatus according to any of clauses 1-14 and an ejection system.
16. A fuel emitter according to clause 15, wherein the ejection system is configured to eject a stream of droplets to a plasma formation location.
17. A fuel emitter according to clause 16, further comprising a droplet monitoring device to monitor the stream of droplets
18. A fuel emitter according to clause 17, further comprising a control unit to adjust a pressure applied by the pressurizing system to the solid target material in the reservoir based on an output of the droplet monitoring device.
19. A fuel emitter according to clause 17, further comprising a control unit to adjust operation of the ejection system based on an output of the droplet monitoring device.
20. A fuel emitter according to clause 17, wherein the apparatus is an apparatus according to clause 6, and wherein the fuel emitter further comprises a control unit to adjust a temperature of the conduit based on an output of the droplet monitoring device.
21. A radiation source for a lithographic tool comprising a fuel emitter according to any of clauses 15-20.
22. A radiation source according to clause 21, wherein the radiation source is configured to output EUV radiation.
23. A radiation source according to clause 21 or 22, wherein the radiation source is a laser produced plasma source.
24. A lithographic apparatus comprising a radiation source according to any of clauses 21-23.
25. A method for supplying liquid target material to a radiation source, comprising pressurizing solid target material in a reservoir and liquifying the solid target material at a distance from the reservoir, wherein the pressure applied to the solid target material is such that the liquid target material is at a pressure of at least 200 bar.
26. A method according to clause 25, wherein the pressure applied to the solid target material is such that the liquid target material entering the ejection system is at a pressure of at least 700 bar, preferably at least 900 bar, more preferably at least 1100 bar, and most preferably at least 1300 ber.

1. An apparatus for supplying a liquid target material to a radiation source, the apparatus comprising a reservoir system including a reservoir configured to be connected to an ejection system via an outlet of the reservoir and a pressurizing system configured to pressurize solid target material in the reservoir, wherein the apparatus further comprises a heating system arranged between the reservoir and the ejection system to liquefy the solid target material after being pressurized in the reservoir, and wherein the pressurizing system is configured to provide a pressure to the solid target material in the reservoir in order to extrude the solid target material through the outlet such that the liquid target material entering the ejection system is at a pressure of at least 200 bar.

2. An apparatus according to claim 1, wherein the pressurizing system is configured to provide a pressure to the solid target material such that the liquid target material entering the ejection system is at a pressure of at least 700 bar, at least 900 bar at least 1100 bar, or at least 1300 bar.

3. An apparatus according to claim 1, wherein the reservoir is configured to receive a billet of solid target material, and wherein the pressurizing system comprises a press that is moveable between a pressing position in the reservoir allowing to engage with and apply pressure to the solid target material in the reservoir, and a retracted position in which a billet of solid target material can be introduced into the reservoir.

4. An apparatus according to claim 1, wherein a conduit is arranged between the reservoir of the reservoir system and the heating system, which conduit is configured to be maintained at a temperature below a melting point of the target material during operation of the apparatus.

5. An apparatus according to claim 1, wherein the reservoir system is a first reservoir system, and wherein the apparatus further comprises a similar second reservoir system configured to be connected to the ejection system in parallel with the first reservoir system.

6. An apparatus according to claim 5, wherein the heating system is a first heating system, and wherein the apparatus further comprises a second heating system configured to liquefy the solid target material after being pressurized in the reservoir of the second reservoir system.

7. A fuel emitter comprising:
an apparatus for supplying a liquid target material to a radiation source, the apparatus comprising:
a reservoir system including a reservoir configured to be connected to an ejection system via an outlet of the reservoir and
a pressurizing system configured to pressurize solid target material in the reservoir,
wherein the apparatus further comprises a heating system arranged between the reservoir and the ejection system to liquefy the solid target material after being pressurized in the reservoir, and wherein the pressurizing system is configured to provide a pressure to the solid target material in the reservoir in order to extrude the solid target material through the outlet such that the liquid target material entering the ejection system is at a pressure of at least 200 bar; and
an ejection system.

8. A fuel emitter according to claim 7, wherein the ejection system is configured to eject a stream of droplets to a plasma formation location.

9. A fuel emitter according to claim 8, further comprising a droplet monitoring device to monitor the stream of droplets.

10. A fuel emitter according to claim 9, further comprising a control unit configured to adjust a pressure applied by the pressurizing system to the solid target material in the reservoir based on an output of the droplet monitoring device.

11. A radiation source for a lithographic tool comprising a fuel emitter according to claim 7.

12. A radiation source according to claim 11, wherein the radiation source is configured to output EUV radiation.

13. A radiation source according to claim 11, wherein the radiation source is a laser produced plasma source.

14. A lithographic apparatus comprising a radiation source according to claim 11.

15. A method for manufacturing integrated circuits comprising the steps of supplying liquid target material to a radiation source, comprising pressurizing solid target material in a reservoir and liquefying the solid target material at a distance from the reservoir, wherein the pressure applied to the solid target material is such that the liquid target material is at a pressure of at least 200 bar.

16. An apparatus according to claim 1, further comprising a vacuum system configured to apply vacuum conditions to the reservoir.

17. An apparatus according to claim 1, further comprising a gas supply system configured to provide an oxide removing gas to the reservoir.

18. An apparatus according to claim 1, further comprising a regulation device configured to control a flow of target material from the reservoir.

19. An apparatus according to claim 3, wherein the pressurizing system comprises a hydraulic system using a hydraulic fluid to apply pressure to the press to move the press from the retracted position to the pressure position.

20. An apparatus according to claim 4, further comprising a temperature control system to regulate the temperature of the conduit.
